(19) United States
(12) Patent Application Publication
(10) Pub. No.: US 2008/0079134 A1
(43) Pub. Date: Apr. 3, 2008

(54) CHIP PACKAGE, CHIP STRUCTURE AND MANUFACTURING PROCESS THEREOF

(75) Inventors: Jui-Chang Lin, Taichung County (TW); Da-Pong Chang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: NOVATEK MICROELECTRONICS CORP., Hsinchu (TW)

(21) Appl. No.: 11/749,167

(22) Filed: May 16, 2007

(30) Foreign Application Priority Data
Sep. 29, 2006 (TW) 95136205

(51) Int. Cl. H01L 23/48; H01L 21/00

(52) U.S. Cl. 257/690; 257/737; 438/113; 257/E21.001; 257/E23.01; 257/E33.056

(57) ABSTRACT

A chip structure including an integrated circuit (IC) element, a plurality of bumps and at least one spacer is provided. The IC element has a plurality of contacts. The bumps are disposed on the contacts respectively. The spacer is disposed on the IC element and between two of the bumps adjacent to each other, and the thickness of the spacer is less than or equal to that of the bumps. Through the arrangement of the spacer, the two bumps are well insulated from each other. Furthermore, a manufacturing process of the chip structure and a chip package with the chip structure are also provided.

### CROSS-REFERENCE TO RELATED APPLICATION

This application claims the priority benefit of Taiwan application serial no. 95136205, filed Sep. 29, 2006. All disclosure of the Taiwan application is incorporated herein by reference.

### BACKGROUND OF THE INVENTION

1. Field of the Invention

The present invention relates to a semiconductor component and a manufacturing process thereof More particularly, the present invention relates to a chip package, a chip structure, and a manufacturing process thereof.

2. Description of Related Art

Along with the advancement of packaging technology, chip on film (COF) bonding technology has become today's one of the major packaging technologies. Generally, COF bonding technology can be applied broadly, for example, the electrical connection between a liquid crystal panel and a drive IC element is one application of COF bonding technology.

With the bonding process between a liquid crystal panel and a drive IC element, a flexible substrate is first provided, wherein a surface of the flexible substrate has a circuit layer thereon, and the circuit layer has a plurality of internal leads. After that, a plurality of drive IC elements are provided, wherein an active surface of each of the drive IC elements has a plurality of gold bumps thereon. Next, the drive IC elements are disposed on the flexible substrate so that the gold bumps are connected to the corresponding internal leads. Then an underfill is filled between the drive IC elements and the flexible substrate. After that, a punching step is performed to divide the flexible substrate disposed with the drive IC elements into a plurality of independent chip packages. Finally, the chip packages are assembled to the liquid crystal panel to form a liquid crystal display module, wherein the drive IC elements are electrically connected to the liquid crystal panel through the flexible substrate.

The chip package obtained through the COF bonding technology has small volume and light weight, and thus the thickness of the liquid crystal display module can be reduced. In addition, since the chip package itself is flexible, such technology further allows the chip package to be easily bent over to the back of the liquid crystal panel after the chip package has been assembled to the front of the liquid crystal panel.

However, it should be noted that before filling the underfill, the active surface of the drive IC element could be contaminated easily by chemical or impurity particles. Therefore, the underfill filled between the drive IC element and the flexible substrate may not be bonded to the active surface of the drive IC element closely, which means there may be many gaps between the underfill and the drive IC element. Accordingly, when the liquid crystal display module is working, part of the gold may easily grow outwardly from the gold bumps and extend along the gaps between the drive IC element and the flexible substrate under the affection of electric field, contamination, and vapor. When the out-growing gold gets into electrical contact with other gold bumps, short circuit between the gold bumps is easily caused, and further the display performance of the liquid crystal display module is affected.

### SUMMARY OF THE INVENTION

According to one aspect of the present invention, the present invention is directed to provide a chip structure and a manufacturing process thereof, wherein the bumps of the chip structure are well insulated from each other.

According to another aspect of the present invention, the present invention is directed to provide a chip package with highly reliable performance.

The present invention provides a manufacturing process of a chip structure. The process includes following steps. First, a wafer is provided, wherein the wafer has a plurality of integrated circuit (IC) elements and each of the IC elements has a plurality of contacts. Bumps are then formed on the contacts respectively. After that, at least one spacer is formed on the IC elements and between two of the bumps adjacent to each other, wherein the material of the spacer is dielectric material and the maximum thickness of the spacer is less than or equal to the thickness of the bumps. Next, the wafer is cut to form a plurality of chip structures.

According to an embodiment of the present invention, the manufacturing process of a chip structure further includes forming at least one metal layer on the wafer before forming the bumps and patterning the metal layer to form a plurality of under bump metal layers after forming the bumps and before forming the spacer, wherein each of the under bump metal layers is between the corresponding bump and contact. Besides, the method for forming the bumps may be plating.

According to the chip structure manufacturing process in an embodiment of the present invention, the method for forming the spacer includes following steps. First, a dielectric layer is formed on the wafer and the bumps. Then, the thickness of the dielectric layer is reduced to make the maximum thickness of the dielectric layer less than or equal to the thickness of the bumps, so that the bumps are exposed.

The present invention provides another manufacturing process of a chip structure. The process includes following steps. First, a wafer is provided. The wafer has a plurality of IC elements and each of the IC elements has a plurality of contacts. Then, at least one spacer is formed on the IC elements and between two of the contacts adjacent to each other, wherein the material of the spacer is dielectric material. Next, a plurality of bumps are formed on the IC elements, wherein the spacer is between two of the bumps adjacent to each other and the maximum thickness of the spacer is less than or equal to the thickness of the bumps. After that the wafer is cut to form a plurality of chip structures.

According to an embodiment of the present invention, the manufacturing process of a chip structure further includes forming at least one metal layer on the wafer after forming the spacer and before forming the bumps and then patterning the metal layer to form a plurality of under bump metal layers after forming the bumps, wherein each of the under bump metal layers is between the corresponding bump and contact. Besides, the method for forming the bumps may be plating.

According to the chip structure manufacturing process in an embodiment of the present invention, the method for forming the spacer includes following steps. First, a dielectric layer is formed on the wafer. The dielectric layer is then patterned to form the spacer.

The present invention provides a chip structure including an IC element, a plurality of bumps, and at least one spacer. The IC element has a plurality of contacts. The bumps are disposed on the contacts respectively. The spacer is disposed on the IC element and between two of the bumps adjacent to each other, wherein the maximum thickness of the spacer is less than or equal to the thickness of the bumps.

According to the chip structure in an embodiment of the present invention, the material of the spacer is dielectric material.

According to an embodiment of the present invention, the chip structure further includes a plurality of under bump metal layers and each of the under bump metal layers is between the corresponding bump and contact.

The present invention provides a chip package including a support structure, a chip structure, and an underfill. The support structure includes a substrate and a circuit layer disposed on a surface of the substrate. The chip structure is disposed on and electrically connected to the support structure. The chip structure includes an IC element, a plurality of bumps, and at least one spacer. The IC element has a plurality of contacts. The bumps are disposed between the contacts and the circuit layer and electrically connect the contacts to the circuit layer. The spacer is disposed on the IC element and between two bumps adjacent to each other, wherein the maximum thickness of the spacer is less than or equal to the thickness of the bumps. The underfill is filled between the chip structure and the support structure and covers the bumps and the spacer.

According to the chip package in an embodiment of the present invention, the material of the spacer is dielectric material.

According to the chip package in an embodiment of the present invention, the substrate is a flexible substrate and the substrate may be formed with a single dielectric layer or by stacking a plurality of dielectric layers and a plurality of circuit layers in a staggered way.

According to the chip package in an embodiment of the present invention, the substrate is a glass substrate.

According to an embodiment of the present invention, the chip package further includes a plurality of under bump metal layers and each of the under bump metal layers is between the corresponding bump and contact.

According to the present invention, at least one spacer is disposed on the IC elements and two of the bumps adjacent to each other, and thus the bumps of the chip structure are well insulated from each other. Accordingly, the chip package in the present invention has high operation reliability.

In order to make the aforementioned and other features and advantages of the present invention comprehensible, an embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1F illustrate a manufacturing process of a chip structure according to an embodiment of the present invention.

FIG. 2A illustrates the appearance of another spacer according to the embodiment of the present invention.

FIG. 2B illustrates the appearance of yet another spacer according to the embodiment of the present invention.

FIGS. 3A-3D illustrate a manufacturing process of a chip structure according to another embodiment of the present invention.

FIG. 4 illustrates a chip package according to an embodiment of the present invention.

### DESCRIPTION OF EMBODIMENTS

The present invention provides a chip structure including an integrated circuit (IC) element, a plurality of bumps, and at least one spacer. The IC element has a plurality of contacts. The bumps are disposed on the contacts. The spacer is disposed on the IC element and between two bumps adjacent to each other, wherein the maximum thickness of the spacer is less than or equal to the thickness of the bumps. The manufacturing process of the chip structure will be described in detail in following embodiments.

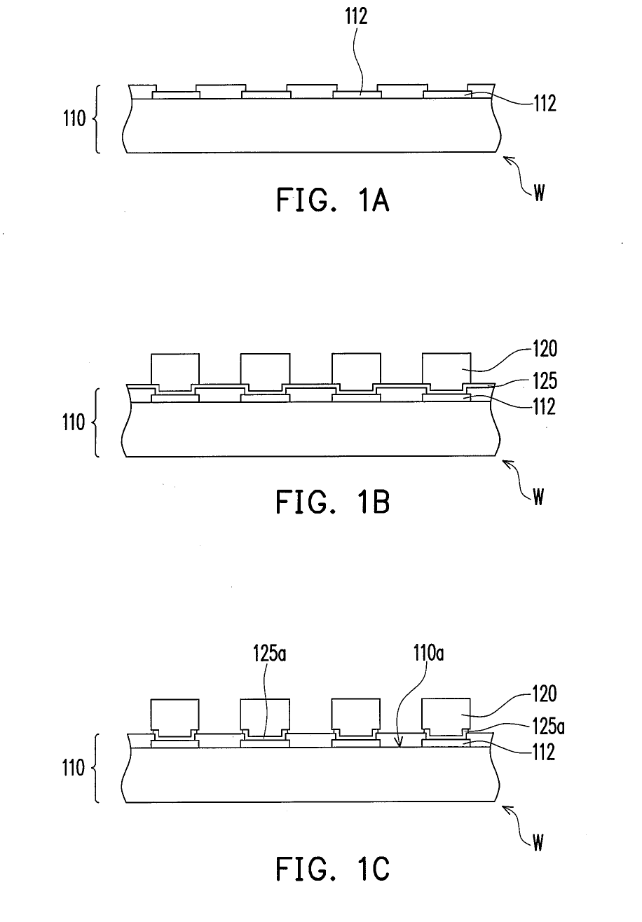

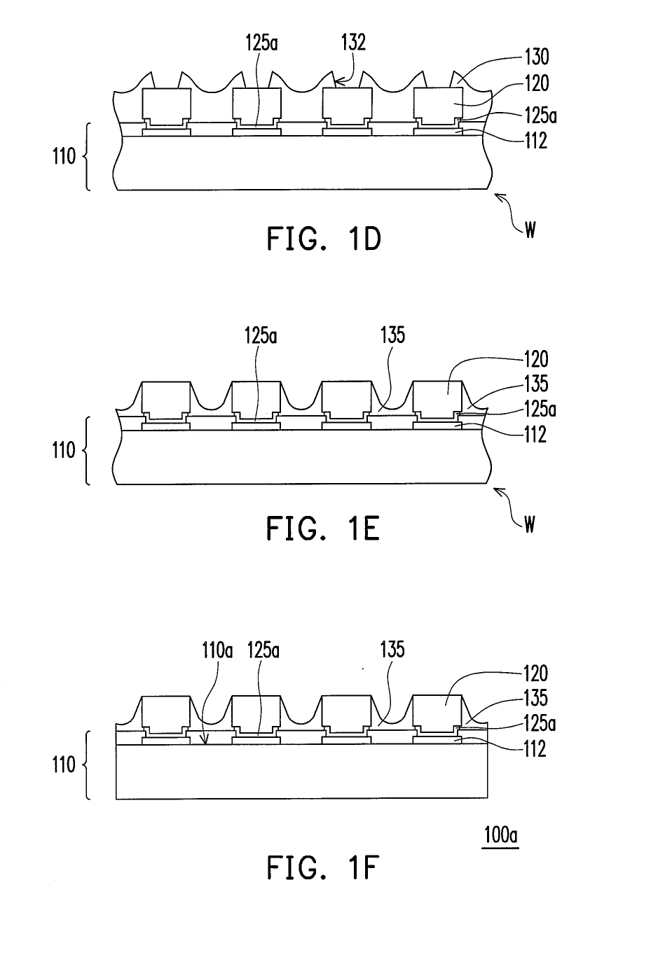

FIGS. 1A-1F illustrate a manufacturing process of a chip structure according to an embodiment of the present invention. Referring to FIG. 1A, a wafer W is first provided. The wafer W has a plurality of IC elements 110, and each of the IC elements 110 has a plurality of contacts 112, wherein the material of the contacts 112 may be aluminum or other conductive material.

Referring to FIG. 1B, bumps 120 are formed on the contacts 112. In the present embodiment, a metal layer 125 is formed on the wafer W through chemical vapor deposition (CVD), sputtering, or other method before forming the bumps 120, wherein the metal layer 125 is electrically connected to the contacts 112. After that, the bumps 120 are formed on the contacts 112 through photolithography and plating, wherein the material of the bumps 120 may be gold or other conductive material. It should be noted that the metal layer 125 may be a single layer of metal or composed of multiple layers of metal.

Referring to FIG. 1C, the metal layer 125 (as shown in FIG. 1B) is patterned to form a plurality of under bump metal layers 125a, wherein the under bump metal layers 125a are located between the bumps 120 and the contacts 112 respectively.

Referring to FIG. 1D, a dielectric layer 130 is formed on the wafer W and the bumps 120 through, for example, spin-coating, wherein the material of the dielectric layer 130 may be silicon oxide, silicon nitride, silicon oxy-nitride, polyimide, spin-on-glass (SOG), or other insulation material. It should be noted that when the dielectric layer 130 is formed on the wafer W and the bumps 120 through method such as spin-coating, the dielectric layer 130 and the surface of the wafer W can be bonded to each other closely without any space in between. Besides, in the present embodiment, a plurality of openings 132 may be further formed on the dielectric layer 130 through dry etching for the subsequent process, wherein the openings 132 expose the top surfaces of the bumps 120.

Referring to FIG. 1E, the thickness of the dielectric layer 130 (as shown in FIG. 1D) is reduced and the maximum thickness of the dielectric layer 130 is made equal to the thickness of the bumps so that the top surfaces of the bumps 120 are exposed completely. Accordingly, a spacer 135 can be formed on the IC elements 110 and between two bumps 120 adjacent to each other, wherein the spacer 135 is bonded to the surface of the wafer W closely.

Referring to FIG. 1F, the wafer W (as shown in FIG. 1E) is cut to form a plurality of chip structures 100a.

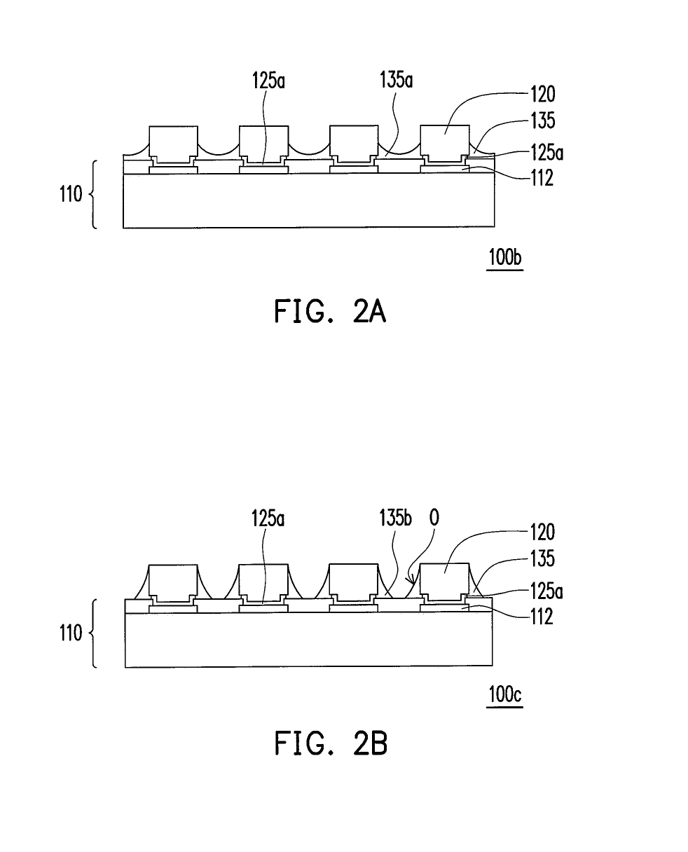

It should be noted that in foregoing FIG. 1F, the appearance of the spacer 135 is not for limiting the present invention. In other embodiments of the present invention, the maximum thickness of the spacer my also be less than the thickness of the bumps 120, as the spacer 135a of the chip structure 100b shown in FIG. 2A. Besides, the spacer may also have an opening, as the opening O of the chip structure 100c shown in FIG. 2B. In other words, the shape of the spacer is not limited by the present invention as long as the spacer is closely bonded to the IC element and disposed between two bumps adjacent to each other, wherein the maximum thickness of the spacer is less than or equal to the thickness of the bumps.

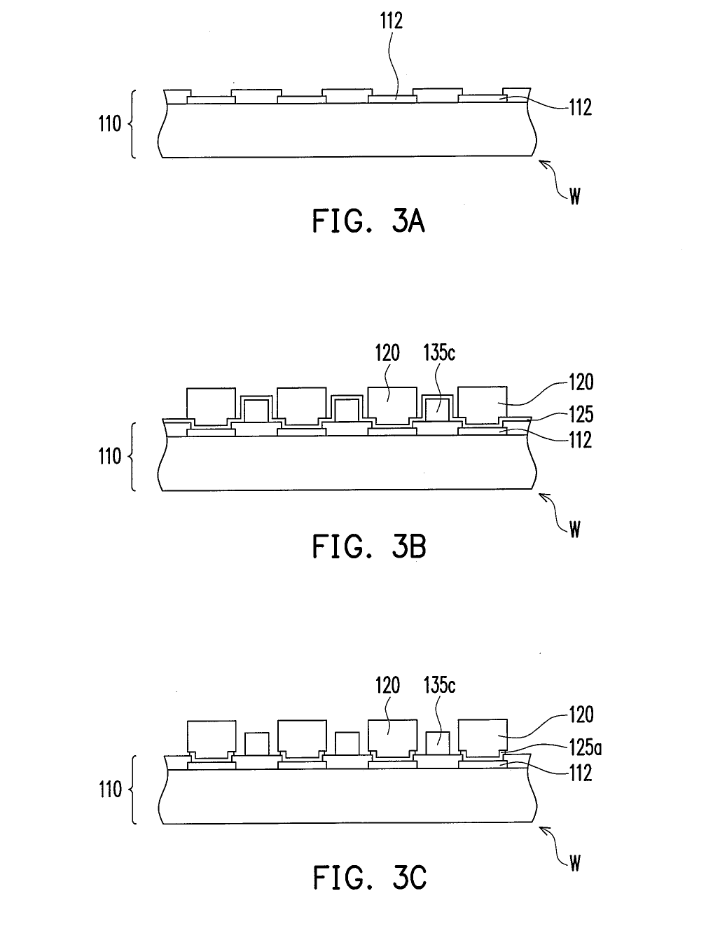

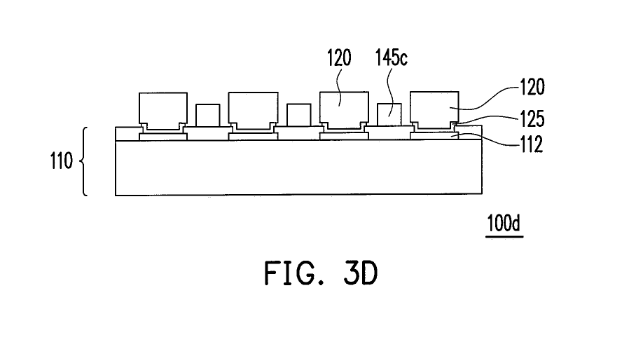

FIGS. 3A-3D illustrate a manufacturing process of a chip structure according to another embodiment of the present invention. Referring to FIG. 3A, a wafer W is first provided. The wafer W has a plurality of IC elements 110, and each of the IC elements 110 has a plurality of contacts 112, wherein the material of the contacts 112 may be aluminum or other conductive material.

Referring to FIG. 3B, at least one spacer 135c is formed on the IC elements 110 and between two contacts 112 adjacent to each other, wherein the material of the spacer 135c is dielectric material. For example, the formation method of the spacer 135c is to form a dielectric layer first on the wafer through spin-coating, wherein the material of the dielectric layer may be silicon oxide, silicon nitride, silicon oxy-nitride, polyimide, SOG, or other insulation material. It should be noted that since the dielectric layer is formed on the wafer and the bumps through spin-coating, the dielectric layer and the surface of the wafer can be bonded to each other closely without any space in between. After that, the dielectric layer is patterned to form the spacer 135c, wherein the spacer 135c is closely bonded to the surface of the wafer W.

Next, a metal layer 125 is formed on the wafer W through CVD, sputtering, or other method, wherein the metal layer 125 and the contacts 112 are electrically connected. After that, a plurality of bumps 120 are formed on the contacts 112 through photolithography and plating, wherein the material of the bumps 120 may be gold or other conductive material, and the maximum thickness of the spacer 135c is less than or equal to the thickness of the bumps. Accordingly, the spacer 135c is between two bumps 120 adjacent to each other. It should be noted that the metal layer 125 may be a single layer of metal or composed of multiple layers of metal.

Referring to FIG. 3C, the metal layer 125 (as shown in FIG. 3B) is patterned to form a plurality of under bump metal layers 125a, wherein the under bump metal layers 125a are located between the bumps 120 and the contacts 112 respectively.

Referring to FIG. 3D, the wafer W is cut to form a plurality of chip structures 100d.

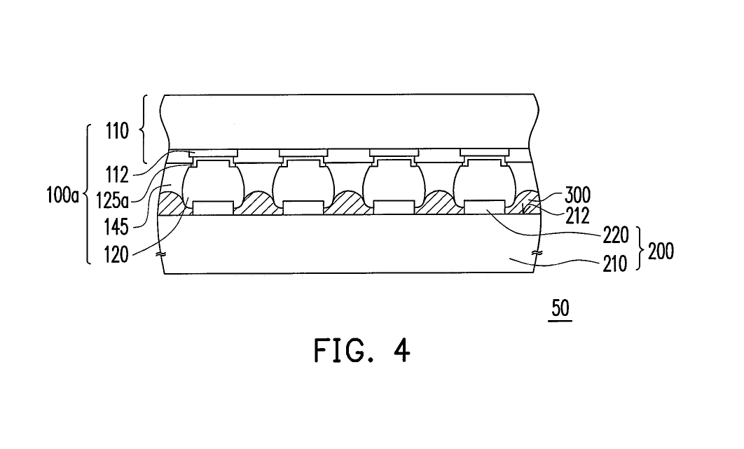

A chip structure and a substrate can be further assembled into a chip package through packaging technology based on the foregoing chip structures 100a, 100b, 100c, and 100d. FIG. 4 illustrates a chip package according to an embodiment of the present invention. Referring to FIG. 4, the chip package 50 includes a chip structure 100a, a support structure 200, and an underfill 300. The support structure 200 includes a substrate 210 and a circuit layer 220. The substrate 210 may be a flexible substrate or a glass substrate. If the substrate 210 is a flexible substrate, it may be a single flexible dielectric layer or formed by stacking a multiple flexible dielectric layers and multiple circuit layers in a staggered way.

The circuit layer 220 is disposed on a surface 212 of the substrate 210. The chip structure 100a is disposed on and electrically connected to the support structure 200, wherein the bumps 120 are located between the contacts 112 and the internal leads of the circuit layer 220 and electrically connect the contacts 112 to the circuit layer 220 respectively. It should mentioned here that if the substrate 210 is a glass substrate, the bumps 120 may electrically connect the contacts 112 and the internal leads of the circuit layer 220 through an anisotropic conductive film (ACF). The underfill 300 is filled between the chip structure 100a and the support structure 200 and covers the bumps 120 of the chip structure 100a and the spacer 135. When the conducting part of the ACF is used to electrically connect the bumps 120 and the contacts 112, the underfill 300 may be the insulating part of the ACF. It should be noted that in the present embodiment, even though the chip structure 100a is disposed on the support structure 200, in other embodiments of the present invention, the chip structure 100b, 100c, or 100d may also be disposed on the support structure 200.

When the chip package is working, the spacer is bonded to the surface of the IC element closely, thus, the spacer can effectively prevent the bump material from growing outwardly or can greatly increase the growing path of the bump material, so as to effectively prevent short circuit between adjacent bumps due to the outward growth of the bump material. Thus, compared to the conventional art, the chip structure in the present invention can improve the insulation between adjacent bumps greatly. Additionally, since short circuit between adjacent bumps due to the outward growth of the bump material is prevented, a chip package with such chip structures provided by the present invention has higher operation reliability.

Besides the foregoing application for resolving the conventional problems in bonding between chip and flexible substrate, the structures and manufacturing process in the present invention may also be applied to bonding between chips and other materials. The structures and manufacturing method in the present invention can effectively prevent short circuit between metal bumps, so that the present invention can be used in any situation wherein metal bumps are used for connection with external circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing process of a chip structure, the manufacturing process comprising:
providing a wafer with a plurality of integrated circuit (IC) elements, each of the IC elements having a plurality of contacts;
forming a plurality of bumps on the contacts respectively;
forming at least one spacer on the IC elements and between two of the bumps adjacent to each other, wherein the material of the spacer is dielectric material, and the maximum thickness of the spacer is less than or equal to the thickness of the bumps; and
cutting the wafer to form a plurality of chip structures.

2. The manufacturing process as claimed in claim 1 further comprising:
forming a metal layer on the wafer before forming the bumps; and
patterning the metal layer to form a plurality of under bump metal layers after forming the bumps and before forming the spacer, wherein each of the under bump metal layers is between the corresponding bump and contact.

3. The manufacturing process as claimed in claim 2, wherein the method for forming the bumps is plating.

4. The manufacturing process as claimed in claim 1, wherein the method for forming the spacer comprises:
forming a dielectric layer on the wafer and the bumps;
reducing the thickness of the dielectric layer so that the maximum thickness of the dielectric layer is less than or equal to the thickness of the bumps to expose the bumps.

5. A manufacturing process of a chip structure, the manufacturing process comprising:
providing a wafer with a plurality of IC elements, wherein each of the IC elements having a plurality of contacts on a surface thereof;
forming at least one spacer on the IC elements and between two of the contacts adjacent to each other, wherein the material of the spacer is dielectric material;
forming a plurality of bumps on the IC elements, wherein the spacer is between two of the bumps adjacent to each other and the maximum thickness of the spacer is less than or equal to the thickness of the bumps; and
cutting the wafer to form a plurality of chip structure.

6. The manufacturing process as claimed in claim 5 further comprising:
forming at least one metal layer on the wafer after forming the spacer and before forming the bumps; and
patterning the metal layer to form a plurality of under bump metal layers after forming the bumps, wherein each of the under bump metal layers is between the corresponding bump and contact.

7. The manufacturing process as claimed in claim 6, wherein the method for forming the bumps is plating.

8. The manufacturing process as claimed in claim 5, wherein the method for forming the spacer comprises:
forming a dielectric layer on the wafer;
patterning the dielectric layer to form the spacer.

9. A chip structure, comprising:
an IC element, having a plurality of contacts on a surface thereof;
a plurality of bumps, disposed on the contacts; and
at least one spacer, disposed on the IC element and between two of the bumps adjacent to each other, wherein the maximum thickness of the spacer is less than or equal to the thickness of the bumps.

10. The chip structure as claimed in claim 9, wherein the material of the spacer is dielectric material.

11. The chip structure as claimed in claim 9 further comprising a plurality of under bump metal layers, wherein each of the under bump metal layers is disposed between the corresponding bump and contact.

12. A chip package, comprising:
a support structure, comprising:
a substrate; and
a circuit layer, disposed on a surface of the substrate;
a chip structure, disposed on the support structure and being electrically connected to the support structure, the chip structure comprising:
an IC element, having a plurality of contacts;
a plurality of bumps, disposed between the contacts and the circuit layer and electrically connecting the contacts to the circuit layer respectively;
at least a spacer, disposed on the IC elements and between two bumps adjacent to each other, wherein the maximum thickness of the spacer is less than or equal to the thickness of the bumps; and
an underfill, filled between the chip structure and the support structure and covering the bumps and the spacers.

13. The chip package as claimed in claim 12, wherein the material of the spacer is dielectric material.

14. The chip package as claimed in claim 12, wherein the substrate is a flexible substrate.

15. The chip package as claimed in claim 14, wherein the substrate comprises a plurality of flexible dielectric layers and a plurality of circuit layers stacked in a staggered way.

16. The chip package as claimed in claim 14, wherein the substrate is a single flexible dielectric layer.

17. The chip package as claimed in claim 12, wherein the substrate is a glass substrate.

18. The chip package as claimed in claim 12 further comprising a plurality of under bump metal layers, wherein each of the under bump metal layers is disposed between the corresponding bump and contact.
